(19) United States
(12) Patent Application Publication
(10) Pub. No.: US 2006/0112209 A1
(43) Pub. Date: May 25, 2006

(54) SD memory card with a USB plug

(76) Inventor: Li-Ho Yao, Taipei (TW)

Correspondence Address: Jackson Walker L.L.P., Suite 2100, 112 E. Pecan Street, San Antonio, TX, 78205, US

(21) Appl. No.: 10/997,512

(22) Filed: Nov. 24, 2004

(51) Int. Cl. H05K 7/10; G06F 12/14

(52) U.S. Cl. 710/301; 711/115

(57) ABSTRACT

An SD memory card integrated with a USB interface plug. Between a top cover and a board, a circuit board is mounted and SD conductive point contacts are set at a first edge, and an extended plate is formed at a second edge. A USB conductive board is applied to add the thickness of the extended plate to meet the USB hub requirement. In this way, SD and USB plugs can be integrated in a single memory card.

### BACKGROUND OF THE INVENTION

1. Field of the Invention

The present invention relates to a memory card, and particularly relates to an SD (secure digital) memory card integrated with a USB (Universal Serial Bus) plug.

2. Description of Related Art

As micro-electronic products, from phones to PDA's to music storage devices, continue to boom in popularity, the trend of the corresponding memory cards is larger capacity and greater compatibility. For example, the standard interfaces of a memory card include: CF (compact flash), MS (message store), SD etc. However, a memory card has only a single plug which can not be compatible to the products with different hubs, so a card reader is provided to read memory cards with different interface plugs.

From another aspect, it is possible for the memory card itself to have multiple interface plugs compatible with various products, and such kind of memory card usually has a second interface plug of USB next to]the original standard plug.

Taking an SD memory card for example, the standard interspace height for an SD hub is 1.4±0.1 mm, thus the plug thickness of the memory card should meet the above requirement; on the other hand, the standard interspace height for a USB hub is at least 1.8 mm, clearly greater than the SD hub. How to integrate the two plugs in a single SD memory card remains a problem.

Therefore, the invention provides an SD card integrated with a USB interface plug to mitigate or obviate the aforementioned problems.

### SUMMARY OF THE INVENTION

The main objective of the present invention is to provide an SD memory card integrated with a USB plug, so either an SD or a USB interface plug can be chosen.

Other objectives, advantages and novel features of the invention will become more apparent from the following detailed description when taken in conjunction with the accompanying drawings.

### BRIEF DESCRIPTION OF THE DRAWINGS

FIG. 1 is an exploded view of an SD memory card in accordance with this invention;

FIG. 2 is a view of the SD memory card in accordance with this invention in a separated status;

FIG. 3 is a perspective view of the SD memory card in accordance with this invention in an assembled status;

FIG. 4 is a plan view of the SD memory card in accordance with this invention; and

FIG. 5 is a cross-sectional view of the SD memory card in accordance with this invention along line 5-5 in FIG. 4.

### DETAILED DESCRIPTION OF THE PREFERRED EMBODIMENT

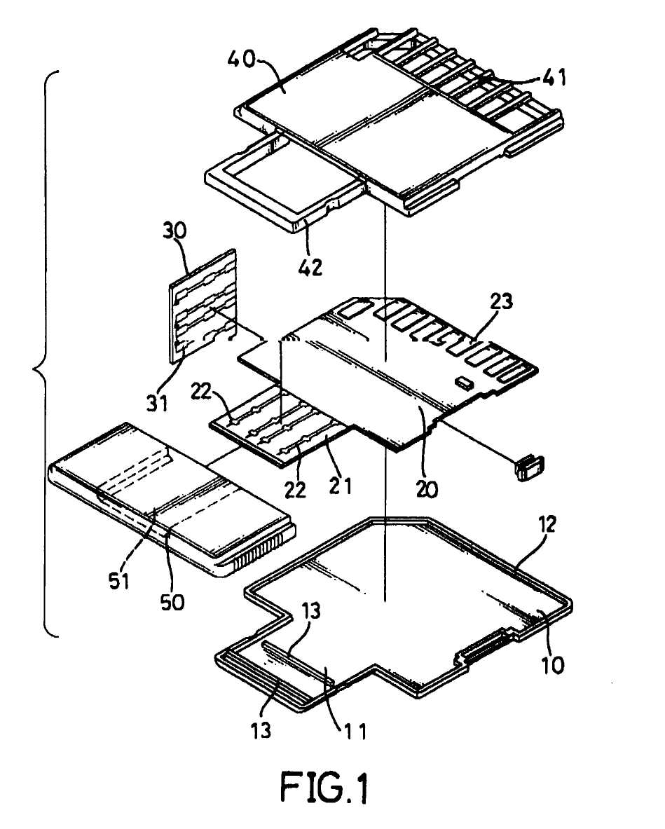

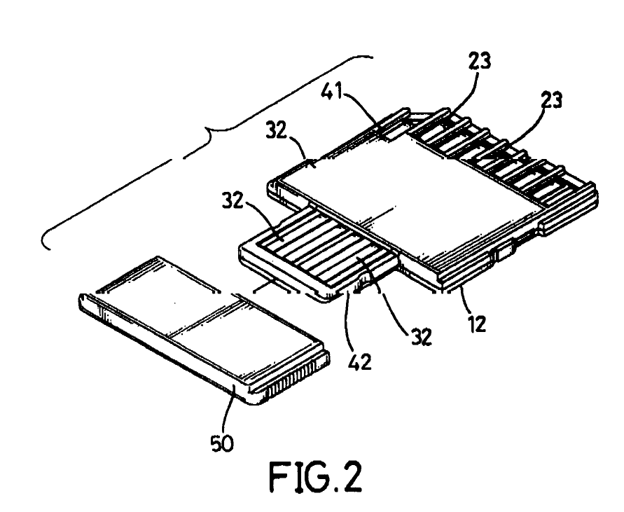

With reference to FIGS. 1 and 2, an SD memory card integrated with a USB interface plug according to this invention has: a board (10), from one side of which a rectangular plate (11) is extended. The board (10) is provided with a uninterrupted top flange (12) extending along the periphery to form a flat structure. One edge of the rectangular plate (11) far from the board (10) is formed with multiple rails (13). A circuit board (20) is the same shape as but is nominally smaller than the board (10), whereby the circuit board (20) can be received in a recess defined by the top flange (12). Corresponding with the rectangular plate (11), an extended plate (21) is formed at a first edge of the circuit board (20), with four first conductive point contacts (22) set thereon. A second edge of the circuit board (20) far from the extended plate (21) is formed as a standard SD plug. A USB conductive board (30) has a same size as the extended plate (21), and four second conductive point contacts (31) and four third conductive point contacts (32) in respective contact with the four second conductive point contacts (31) are provided respectively in an upper end and a lower end of the USB conductive board (30), wherein each second conductive point contact (31) touches the corresponding first conductive point contact (22) when the USB conductive board is fitted to the extended plate (21).

A top cover (40) rests on the board (10) to secure the circuit board (20) and the USB conductive board (30). A first end of the top cover (40) has multiple parallel ribs (41) formed into a grille structure, and each space between two neighboring ribs is corresponds to an SD conductive point contact (23) in the second edge of the circuit board (20). A second end of the top cover (40) has an extended frame (42).

A rear cap (50) corresponding to the rectangular plate (11) has a cutout (51) formed in an under-face thereof and the cutout (51) has an opening defined on one edge of the rear cap.

The assembly operation is: the USB conductive board (30) is superposed on the extended plate (21) of the circuit board (20), so the four second conductive point contacts (31) respectively touch the four first conductive point contacts (22). The conductive board (30) and the circuit board (20) are secured on the board (10) by the top flange, and then the top cover (40) is rested on the board (10).

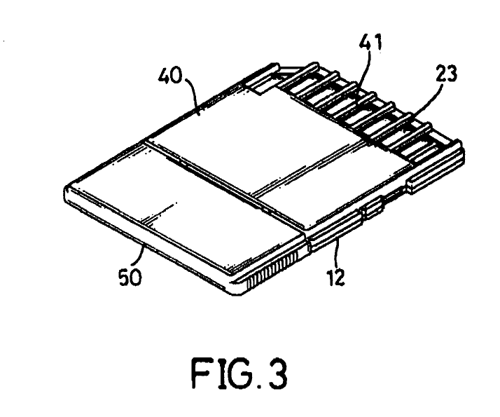

With reference to FIG. 2, as the first end of the top cover (40) is formed as the grille structure and the second end has the extended frame (42), so the SD conductive point contact (23) and the third conductive point contacts (32) are exposed. When the plug of the memory card is inserted into an SD or USB hub, those conductive point contacts can touch the corresponding contact points in the hub. When the assembly operation is completed, a USB plug is formed, as shown in FIG. 2. Referring to FIG. 3, when the rear cap (50) is fitted to cover the USB plug, the card performs as a standard SD memory card and can be applied in an SD hub. The data in USB plug can be accessed by removing the rear cap (50).

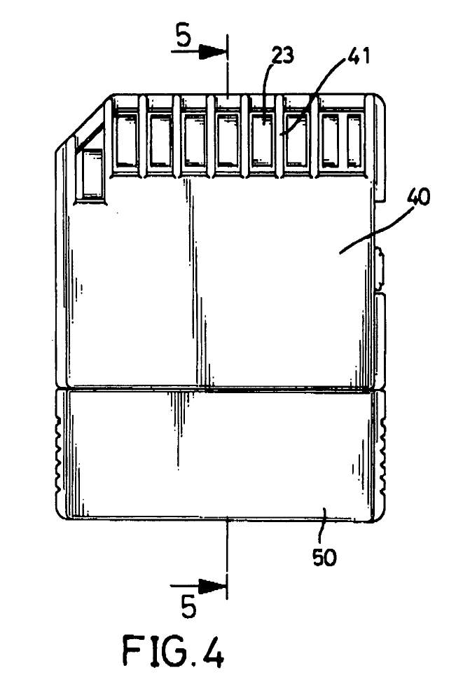

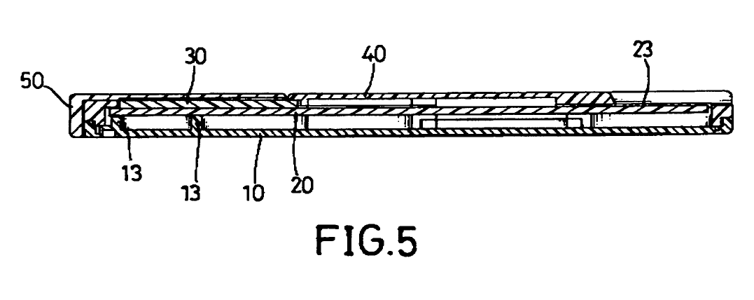

With reference to FIG. 4 and FIG. 5, when the circuit board (20) is secured in the board (10), the entire height is 1.4±0.1 mm which meets the requirement of an SD hub, but not the USB hub which has aperture height of 1.8 mm. To solve this problem, the conductive board (30) is applied to compensate the height difference. Meanwhile, the rails (13) in the board (10) supply a reinforcement to the extended plate (21) and the conductive board (30).

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An SD memory card integrated with a USB interface plug comprising:
a board (10), from one side of which extends a plate (11);
a circuit board (20) configured to mate with the board (10) and having an extended plate (21) being formed at a first edge of the circuit board (20), with multiple first conductive point contacts (22) set thereon; a second edge of the circuit board (20) far from the extended plate (21) and formed as a standard SD plug (23);
a USB conductive board (30) mounted on the extended plate (21), and having multiple second conductive point contacts (31) and multiple third conductive point contacts (32) respectively contacting the multiple second conductive point contacts, the multiple second and third conductive point contacts provided respectively in an upper surface and a lower surface of the USB conductive board (30), wherein each second conductive point contact (31) touches the respective first conductive point contact (22); and
a top cover (40) mounted on the board (10) to secure the circuit board (20) and the USB conductive board (30), a first end of the top cover (40) formed into a grille structure, a second end of the top cover (40) having an extended frame (42).

2. The SD memory card integrated with a USB interface plug as defined in claim 1, wherein the extended frame (42), the USB conductive board (30), the extended plate (21) and the rectangular plate (11) are mounted together to form the USB plug, which is covered by a rear cap (50), wherein a cutout (51) is formed corresponding to the rectangular plate (11).

3. The SD memory card integrated with a USB interface plug as defined in claim 2, wherein the grille structure is formed by multiple parallel ribs (41), and each interspace between two neighboring ribs is corresponds to a respective SD conductive point contact (23) in the second edge of the circuit board (20).
